(19) United States
(12) Patent Application Publication
(10) Pub. No.: US 2025/0109894 A1
(43) Pub. Date: Apr. 3, 2025

(54) JET FLOW EVAPORATIVE COOLING SYSTEM

(71) Applicant: CANON KABUSHIKI KAISHA, Tokyo (JP)

(72) Inventors: KAZUYA TSUJINO, Tokyo (JP); YUI SAKUMA, Tochigi (JP)

(21) Appl. No.: 18/900,369

(22) Filed: Sep. 27, 2024

(30) Foreign Application Priority Data
Oct. 2, 2023 (JP) 2023-171697

(51) Int. Cl. F25B 19/04; H05K 7/20

(52) U.S. Cl. CPC F25B 19/04; H05K 7/20327

(57) ABSTRACT

A jet flow evaporative cooling system that cools a heat generation unit with a jet flow of liquid includes a heat transfer portion integrally formed with a cooling portion configured to receive the jet flow of liquid and an arrangement portion on which the heat generation unit is arranged, an opening portion configured to jet a liquid supplied from a supply portion to the cooling portion, a drain portion configured to drain the liquid, and a chamber configured to accommodate the opening portion, the drain portion, and the cooling portion and configured to not accommodate the arrangement portion therein, wherein the chamber is maintained under a reduced pressure environment, wherein the opening portion is configured to jet the liquid to the cooling portion, wherein at least a part of the cooling portion is inclined, and wherein the liquid is drained from the drain portion via the cooling portion.

### BACKGROUND

### Field of the Disclosure

The present disclosure relates to a jet flow evaporative cooling system that cools a heat generation unit with a jet flow of liquid.

### Description of the Related Art

Heat generation density of various devices tends to increase due to higher integration of devices and higher sophistication of industrial devices in recent years. In order to cool these various devices, there is a challenge to efficiently remove heat from high heat fluxes (amount of heat passing through a certain surface per unit area per unit time) via a cooling portion, which is a part of a heat transfer unit that is in thermally contact with these devices. Cooling methods of cooling apparatuses having the above-described functions include sensible heat cooling that cools a cooling portion using a temperature difference between a refrigerant, such as gas and liquid, and the cooling portion being in contact with the refrigerant, and evaporative cooling that cools a cooling portion using latent heat (vaporization heat) required for a refrigerant to boil and vaporize.

Main types of evaporative cooling are ebullient cooling, in which a cooling portion is immersed in a refrigerant and cooled by boiling of the refrigerant and a method for jetting a refrigerant from an opening portion, such as a nozzle, to a cooling portion and vaporizing the refrigerant to cool the cooling portion (herein referred to as jet flow evaporative cooling). According to Japanese Unexamined Patent Application Publication (Translation of PCT Application) No. 2003-509874, a technique for jetting a cooling liquid from a nozzle disposed above a circuit board in order to cool a semiconductor device provided on the circuit board is discussed.

However, in a cooling method using a jet flow of liquid, cooling efficiency may be reduced in some cases due to an obstruction to a jet flow caused by a cooling liquid that has not been vaporized by a heat source and remains on a cooling surface or an obstruction to a jet flow caused by a jetted cooling liquid falling by gravity and reaching an opening portion of a nozzle.

### SUMMARY

According to an aspect of the present disclosure, a jet flow evaporative cooling system that cools a heat generation unit with a jet flow of liquid includes a heat transfer portion integrally formed with a cooling portion configured to receive the jet flow of liquid and an arrangement portion on which the heat generation unit is arranged, an opening portion configured to jet a liquid supplied from a supply portion to the cooling portion, a drain portion configured to drain the liquid, and a chamber configured to accommodate the opening portion, the drain portion, and the cooling portion and configured to not accommodate the arrangement portion therein, wherein the chamber is maintained under a reduced pressure environment, wherein the opening portion is configured to jet the liquid to the cooling portion, wherein at least a part of the cooling portion is inclined, and wherein the liquid is drained from the drain portion via the cooling portion.

Further features of various embodiments will become apparent from the following description of exemplary embodiments with reference to the attached drawings.

### BRIEF DESCRIPTION OF THE DRAWINGS

FIG. 1 is a schematic diagram illustrating a jet flow evaporative cooling system according to a first exemplary embodiment.

FIGS. 2A to 2D are diagrams illustrating modifications of an inclined portion in the jet flow evaporative cooling system according to the first exemplary embodiment.

FIG. 3 is a schematic diagram illustrating a jet flow evaporative cooling system according to a second exemplary embodiment.

FIG. 4 is a diagram illustrating a modification of an inclined portion in the jet flow evaporative cooling system according to the second exemplary embodiment.

FIGS. 5A and 5B are diagrams illustrating modifications of a cooling portion according to the first or the second exemplary embodiment.

FIG. 6 is a schematic diagram illustrating a jet flow evaporative cooling system according to a third exemplary embodiment.

FIG. 7 is a schematic diagram illustrating a jet flow evaporative cooling system according to a fourth exemplary embodiment.

FIGS. 8A to 8C are schematic diagrams illustrating modifications of a partition portion in the jet flow evaporative cooling system according to the fourth exemplary embodiment.

FIG. 9 is a schematic diagram illustrating a jet flow evaporative cooling system according to a fifth exemplary embodiment.

FIG. 10 is a schematic diagram illustrating a modification of a partition portion in the jet flow evaporative cooling system according to the fifth exemplary embodiment.

FIG. 11 is a schematic diagram illustrating a jet flow evaporative cooling system according to a sixth exemplary embodiment.

FIG. 12 is a schematic diagram illustrating a jet flow evaporative cooling system according to a seventh exemplary embodiment.

### DESCRIPTION OF THE EMBODIMENTS

Exemplary embodiments of a jet flow evaporative cooling system according to the present disclosure will be described below with reference to the attached drawings. The same or equivalent components, members, and processing illustrated in the drawings are denoted by the same reference numerals, and redundant description will be omitted. In addition, configurations in each exemplary embodiment may be appropriately combined and implemented.

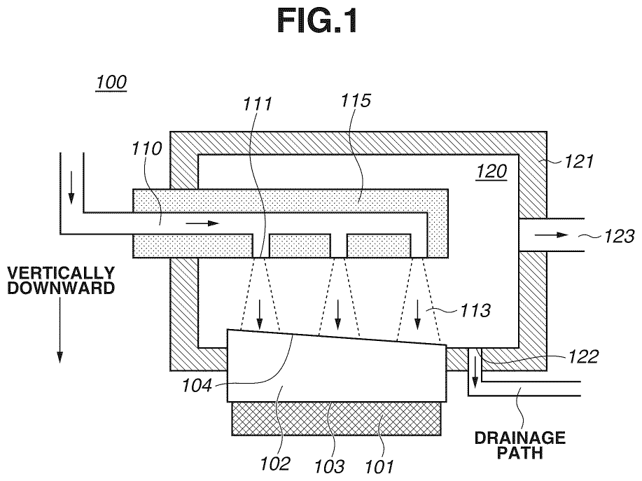

FIG. 1 is a diagram illustrating a configuration of a jet flow evaporative cooling system 100 around a heat generation unit according to a first exemplary embodiment of the present disclosure. The jet flow evaporative cooling system 100 according to the present exemplary embodiment jets a liquid supplied from a supply portion 110 to a cooling portion (also referred to as cooling surface) 104, where a heat generation unit 101 is arranged, to cool the heat generation unit 101.

The jet flow evaporative cooling system 100 according to the present exemplary embodiment includes the cooling portion 104 that receives a jet flow of liquid, an arrangement portion 103 on which the heat generation unit 101 is arranged, a heat transfer portion 102 that is integrated with the cooling portion 104 and the arrangement portion 103, and an opening portion 111 that jets the liquid supplied from the supply portion 110 to the cooling portion 104. The jet flow evaporative cooling system 100 also includes a chamber 121 configured to accommodate a drain portion 122 for draining the liquid, the opening portion 111, and the cooling portion 104 but not to accommodate the arrangement portion 103 therein. The jet flow evaporative cooling system 100 is configured such that, while the chamber 121 is maintained under a reduced pressure environment, the opening portion 111 ejects a jet of a refrigerant 113 to the cooling portion 104, a part of the cooling portion 104 is included, and liquid is drained from the drain portion 122 via the cooling portion 104. Here, the cooling portion 104 is configured to incline with respect to a plane formed by the arrangement portion 103. With this configuration, providing the jet flow evaporative cooling system 100 for the heat generation unit 101 enables the liquid to be efficiently drained via the cooling portion 104.

Each component included in the jet flow evaporative cooling system 100 is described below.

The heat generation unit 101 is in thermal contact with the arrangement portion 103, which is a part of the heat transfer portion 102, and heat generated in the heat generation unit 101 is transferred via the heat transfer portion 102 to the cooling portion 104, which is a part of the heat transfer portion 102. The heat transfer portion 102, the arrangement portion 103, and the cooling portion 104 do not necessarily have to be configured as an integrated component, and they may be configured from different members. Each of the members may be subjected to interface treatment to reduce thermal resistance and integrated as one component made of different members.

The heat transfer portion 102 is made of a material with high thermal conductivity, such as copper, aluminum, or an alloy thereof, and has an appropriate thickness in order to quickly transfer the heat generated in the heat generation unit 101 to the cooling portion 104.

The arrangement portion 103 is appropriately in contact with the heat generation unit 101, for example, by being tightly adhered thereto using thermal grease or the like, so that a temperature difference (thermal resistance) between the heat generation unit 101 and the heat transfer portion 102 is small. With this configuration, the cooling portion 104 is cooled, so that the heat generated in the heat generation unit 101 can be removed, and the heat generation unit 101 can be quickly cooled.

The jet flow evaporative cooling system 100 includes a jet unit 115 that includes the supply portion 110 that supplies the refrigerant and the opening portion 111 that ejects a jet of the refrigerant to the cooling portion 104, and the chamber 121 that accommodates the cooling portion 104 and the drain portion 122 that drains the refrigerant therein and forms a space 120. The chamber 121 can be applied to cooling of various types of heat sources by being brought into contact with the heat generation unit 101 as a cooling target via the heat transfer portion 102. A shape of the opening portion 111 may be appropriately determined by a user so that cooling performance suitable for a purpose can be obtained.

In FIG. 1, three openings are provided in the opening portion 111, but the present exemplary embodiment is not limited to this configuration, and the number and arrangement of the openings may be appropriately set by a user. For example, a single opening may be provided, or openings may be provided in two directions.

An example in which the supply portion 110 supplies the refrigerant to each of the plurality of openings of the opening portion 111 is illustrated, but the present exemplary embodiment is not limited to this configuration, and the supply portion 110 may be provided individually for each opening of the opening portion 111.

Since the heat generation unit 101 is disposed outside the space 120, the jet flow evaporative cooling system 100 does not need to consider effects of the characteristics of the refrigerant (an electrical insulation characteristic, a chemical characteristic, and the like) on the heat generation unit 101. Thus, the refrigerant may be appropriately selected according to an intended performance of the jet flow evaporative cooling system 100. Various refrigerants can be used for evaporative cooling, including water, ethanol, and fluorine-based inert liquids. In a case where the intended performance is to remove heat from a high heat flux, it is desirable to use a refrigerant containing water as a main component, since water has a very large vaporization heat that significantly affects the cooling ability and is also superior in terms of safety, cost, and the like.

The space 120 inside the chamber 121 is under a reduced pressure environment in which a degree of vacuum is adjusted in advance using a means for exhaust air from an exhaust portion 123, or the like. In other words, the jet flow evaporative cooling system 100 may further include a decompression unit that reduces the pressure in the chamber 121 via the exhaust portion 123. The degree of vacuum may be adjusted so that the boiling point of the refrigerant is at a temperature intended by the user. For example, in a case where water is used as the refrigerant and the boiling point is to be set to approximately 33° C., the degree of vacuum in the space 120 can be set to 5 kPa.

The jet flow evaporative cooling system 100 causes the refrigerant 113 to pass through the supply portion 110 and be jetted from the opening portion 111 to the cooling portion 104. If the temperature of the cooling portion 104 becomes higher than the boiling point of the refrigerant due to the heat generated in the heat generation unit 101, the refrigerant vaporizes into steam, and the cooling portion 104 is cooled by the vaporization heat. The steam of the refrigerant generated on the cooling portion 104 is exhausted from the exhaust portion 123, so that the degree of vacuum in the space 120 can be maintained. However, the present exemplary embodiment is not limited to this configuration.

The drain portion 122 is appropriately disposed so that the liquid of the refrigerant 113 that has been jetted to the cooling portion 104 but has remained unvaporized is drained to the outside of the chamber 121. In the jet flow evaporative cooling system 100 according to the first exemplary embodiment, the chamber 121 is arranged so that the arrangement portion 103 is vertically below the opening portion 111, and the cooling portion 104 is inclined with respect to a vertical direction as illustrated in FIG. 1. Further, at least a part of the drain portion 122 is set vertically below the cooling portion 104 so that the refrigerant that has not been vaporized can be quickly drained via an incline of the cooling portion 104. The jet flow evaporative cooling system 100 according to the present exemplary embodiment has the above-described configuration and thus can prevent the liquid that has not been vaporized from remaining on the cooling portion 104 and obstructing the jet flow of liquid ejected from the opening portion 111, thereby being able to provide cooling with stable cooling efficiency.

### First Modification

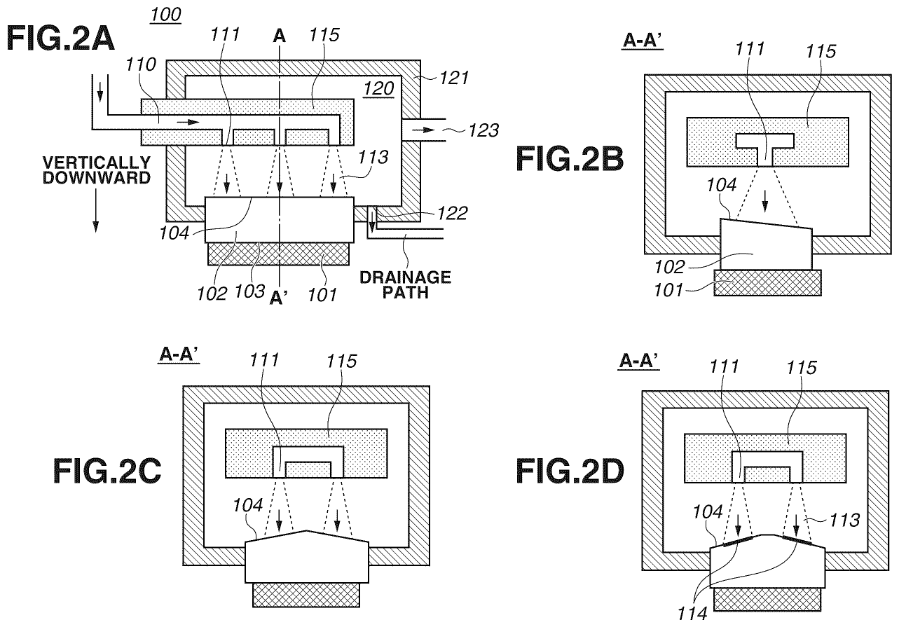

FIGS. 2A to 2D illustrate examples in which an inclined portion of the cooling portion 104 included in the jet flow evaporative cooling system 100 is different from that in FIG. 1. According to the first exemplary embodiment, an example is described in which the cooling portion 104 is inclined in a direction toward the drain portion 122 in the jet flow evaporative cooling system 100, but the incline of the cooling portion 104 is not limited to the above-described example. For example, the cooling portion 104 may be horizontal to a direction of a drainage path as illustrates in FIG. 2A and may be inclined in a direction different from that in FIG. 1 as illustrated in FIG. 2B, which is a cross-sectional view taken along line A-A′ in FIG. 2A. In addition, the cooling portion 104 may be inclined in a plurality of directions as illustrated in FIG. 2C. Further, a jet flow collision portion (also referred to as a jet flow collision range) 114 where the jet flow of liquid ejected from the opening portion 111 collides against the cooling portion 104 may be inclined as illustrated in FIG. 2D. With the configuration, the refrigerant that has not been vaporized can be prevented from remaining on the jet flow collision portion 114, and the jet flow evaporative cooling can be performed with stable cooling efficiency.

According to the first exemplary embodiment and the first modification, the liquid refrigerant that has not been vaporized at the cooling portion 104 quickly moves on the cooling portion 104 by the incline formed thereon and is drained from the drain portion 122. Accordingly, the momentum of the jet flow ejected from the opening portion 111 to the cooling portion 104 is less likely to be obstructed, and the temperature of the cooling portion 104 can be stably controlled.

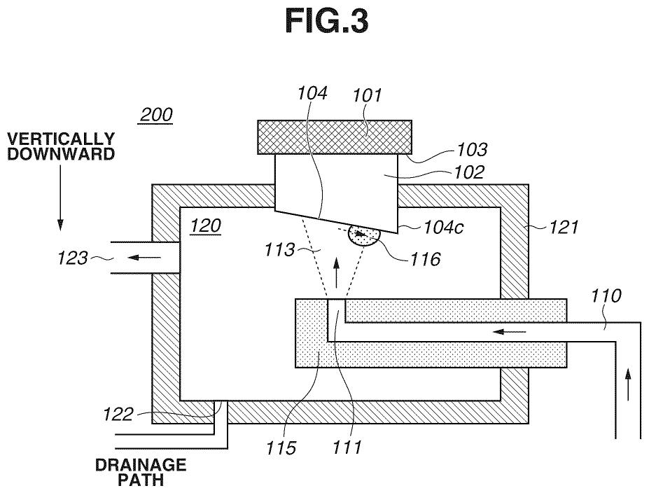

A jet flow evaporative cooling system 200 according to a second exemplary embodiment of the present disclosure is described with reference to FIG. 3. FIG. 3 is a schematic diagram illustrating the jet flow evaporative cooling system 200 according to the second exemplary embodiment. According to the first exemplary embodiment, the cooling portion 104 is disposed vertically below the opening portion 111. On the other hand, in the jet flow evaporative cooling system 200 according to the second exemplary embodiment, the chamber 121 is arranged in which the cooling portion 104 is disposed vertically above the opening portion 111.

Further, the cooling portion 104 included in the jet flow evaporative cooling system 200 according to the second exemplary embodiment is inclined with respect to the vertical direction and includes a vertical lower portion 104c, which is a lowest part of the cooling portion 104.

The second exemplary embodiment includes the same configuration as that in FIG. 1, except that the opening portion 111 is arranged at a position different from a position vertically directly below the vertical lower portion 104c of the cooling portion 104, and the drain portion 122 is located vertically below the opening portion 111. In other words, the opening portion 111 is disposed at a position different from the position of the vertical lower portion 104c that is located at the lowest position of the cooling portion 104.

A non-vaporized refrigerant 116 that has not been vaporized of the refrigerant 113 jetted from the opening portion 111 to the cooling portion 104 does not quickly fall vertically downward due to an effect of surface tension but moves to the vertical lower portion 104c along the incline of the cooling portion 104 and then falls.

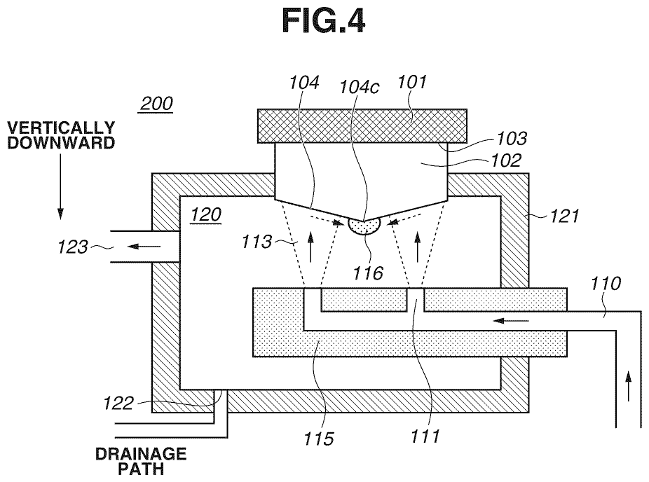

FIG. 3 illustrates an example of the incline of the cooling portion 104 according to the second exemplary embodiment, but the present exemplary embodiment is not limited to this example and may be configured such that, for example, the cooling portion 104 has a plurality of inclines or a plurality of openings is formed in the opening portion 111, as illustrated in FIG. 4. The jet flow evaporative cooling system 200 according to the present exemplary embodiment has the above-described configuration, so that a jet flow evaporative cooling system with stable cooling efficiency can be provided. Specifically, even if the non-vaporized refrigerant 116 that is the liquid not vaporized by the heat generation unit 101 falls due to gravity, the jet flow of the refrigerant 113 from the opening portion 111 can be prevented from being obstructed.

### Second Modification

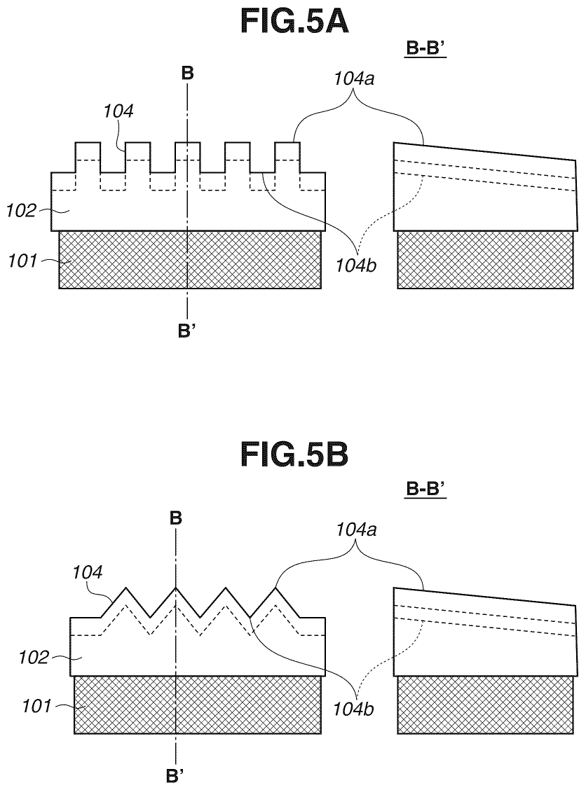

A modification of the cooling portion 104 included in the heat transfer portion 102 according to the first or the second exemplary embodiment of the present disclosure is described with reference to FIGS. 5A and 5B. FIG. 5A is a cross-sectional view illustrating a configuration around the heat transfer portion 102.

FIG. 5A illustrates an example in which the cooling portion 104 included in the heat transfer portion 102 according to the first or the second exemplary embodiment is provided with a groove portion constituted by an upper groove portion 104a and a lower groove portion 104b, and the upper groove portion 104a and the lower groove portion 104b are inclined in a direction in which the grooves of the groove portion extend.

A shape of the groove portion is not limited to that illustrated in FIG. 5A and may be, for example, a shape illustrated in FIG. 5B or may be combined with the configuration of the cooling portion 104 illustrated in FIGS. 1 and 2A to 2D. Further, the shape, width, depth, pitch, and others of the groove portion may be appropriately set.

With the configuration according to the second modification, a contact area between the cooling portion 104 and the jetted liquid can be increased, and the area that allows the liquid to vaporize is increased, so that the cooling efficiency can be further improved while maintaining the effects of the first or the second exemplary embodiment.

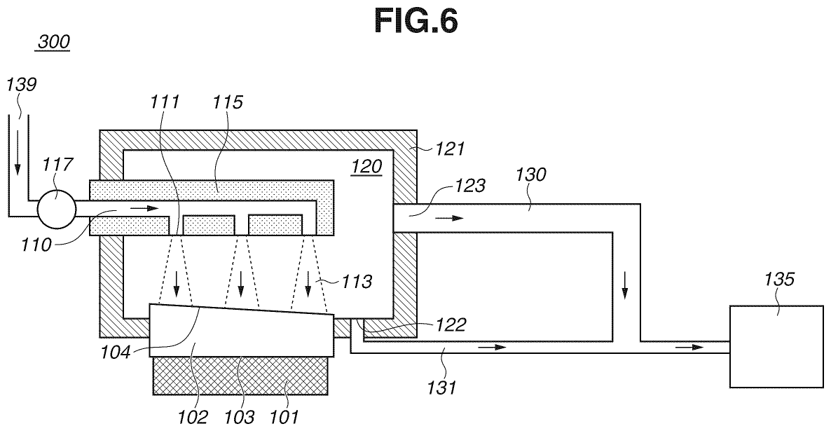

A jet flow evaporative cooling system 300 according to a third exemplary embodiment of the present disclosure is described with reference to FIG. 6. FIG. 6 illustrates an example of an overall configuration of the jet flow evaporative cooling system 300.

FIG. 6 illustrates an example in which the jet flow evaporative cooling system 300 has a functional configuration similar to that of the jet flow evaporative cooling system 100 around the heat generation unit 101 in FIG. 1 according to the first exemplary embodiment, but the present exemplary embodiment is not limited to this configuration and may have the configurations described according to the first and second exemplary embodiments and the first and second modifications.

In the jet flow evaporative cooling system 300 illustrated in FIG. 6, the refrigerant before passing through a refrigerant supply valve 117 is maintained at a pressure equal to or higher than atmospheric pressure. Then, if the refrigerant supply valve 117 is opened, the refrigerant is supplied from a refrigerant delivery unit 139 to the supply portion 110 that supplies the liquid, due to a pressure difference with the pressure in the space 120 inside the chamber 121.

The steam of the refrigerant generated by vaporization on the cooling surface 104 is exhausted by a decompression pump 135 from the exhaust portion 123 disposed in the chamber 121 via an exhaust path 130.

The decompression pump 135 may be, for example, a gear pump, a water seal type pump, or a water ejector, but is not limited to these and may be appropriately selected according to a user's application and environment.

The refrigerant that has not been vaporized on the cooling surface 104 is also collected by the decompression pump 135 from the drain portion 122 via a drainage path 131, but the present exemplary embodiment is not limited to this configuration. The remained liquid may be drained by a separately provided pump (not illustrated) or the like, for example.

Even if a heat generation amount of the heat generation unit 101 or the like is changed, the temperature of the cooling portion 104 can be stably controlled by controlling a flow rate of the refrigerant or the like, but, in order to simplify the description, a control system for controlling them and detailed components, such as a thermometer, a vacuum gauge, and a vacuum valve, are omitted here.

The entire configuration of the jet flow evaporative cooling system 300 is not limited to the above-described configuration and may be appropriately set according to a user's application, environment, and the like.

According to the present exemplary embodiment, an increase in the boiling point of the refrigerant can be suppressed by maintaining the space 120 in a reduced pressure state while cooling the cooling portion 104 by jet flow evaporative cooling. Accordingly, the temperature of the cooling portion 104 can be stably controlled, and the jet flow evaporative cooling system 300 with stable cooling efficiency can be provided.

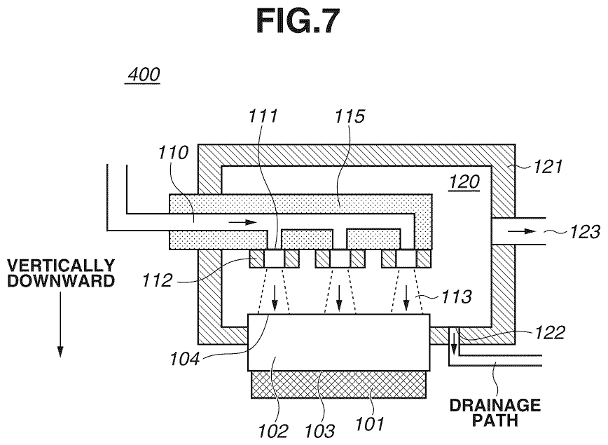

A jet flow evaporative cooling system 400 according to a fourth exemplary embodiment is described below with reference to FIG. 7. The fourth to sixth exemplary embodiments described below may be appropriately combined with the above-described configurations according to the first to third exemplary embodiments.

The jet flow evaporative cooling system 400 according to the present exemplary embodiment is a cooling system that cools the heat generation unit 101 with a jet flow of liquid. The jet flow evaporative cooling system 400 includes the heat transfer portion 102 disposed near the heat generation unit 101 and the jet unit 115. The jet unit 115 includes the opening portion 111 that jets a liquid supplied from the supply portion 110 to the heat transfer portion 102 and a partition portion 112. The jet flow evaporative cooling system 400 further includes the chamber 121 that accommodates a part of the heat transfer portion 102 and the jet unit 115. In the jet unit 115, the partition portion 112 is disposed near the opening portion 111 to surround the openings of the opening portion 111, and the jet unit 115 maintains the chamber 121 in the reduced pressure environment. Further, the opening portion 111 accommodated in the chamber 121 is configured to jet the liquid to a second portion (the cooling portion 104) of the heat transfer portion 102 which is different from a first portion (the arrangement portion 103) of the heat transfer portion 102 in which the heat generation unit 101 is disposed.

FIG. 7 illustrates a configuration of the jet flow evaporative cooling system 400 according to the fourth exemplary embodiment.

Each component included in the jet flow evaporative cooling system 400 is described below.

The heat generation unit 101 is in thermal contact with the arrangement portion 103, which is a part of the heat transfer portion 102, and the heat generated in the heat generation unit 101 is transferred via the heat transfer portion 102 to the cooling portion 104, which is a part of the heat transfer portion 102.

The heat transfer portion 102 is made of a material with high thermal conductivity, such as copper, aluminum, or an alloy thereof, and has an appropriate thickness in order to quickly transfer the heat generated in the heat generation unit 101 to the cooling portion 104.

The arrangement portion 103 is appropriately in contact with the heat generation unit 101, for example, by being tightly adhered thereto using thermal grease or the like, so that the temperature difference (thermal resistance) between the heat generation unit 101 and the heat transfer portion 102 is small. With this configuration, the cooling portion 104 is cooled, so that the heat generated in the heat generation unit 101 can be removed, and the heat generation unit 101 can be quickly cooled.

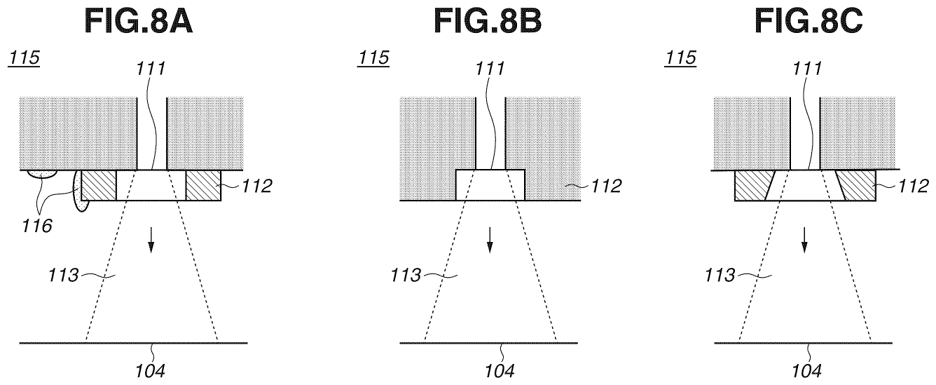

The jet flow evaporative cooling system 400 according to the present exemplary embodiment includes the supply portion 110 that supplies the refrigerant 113, and the jet unit 115 including the opening portion 111 that jets the refrigerant 113 to the cooling portion 104 and the partition portion 112. The jet flow evaporative cooling system 400 further includes the chamber 121 that accommodates the jet unit 115, the cooling portion 104, and the drain portion 122 that drains the refrigerant and forms the space 120. A shape and an effect of the partition portion 112, which are features of the present exemplary embodiment, are described below with reference to FIGS. 8A to 8C.

The shape of the opening portion 111 may be appropriately determined by a user so that cooling performance suitable for a purpose can be acquired.

In FIG. 7, three openings are provided in the opening portion 111, but the present exemplary embodiment is not limited to this configuration, and the number and arrangement of the openings of the opening portion 111 may be appropriately set by a user. For example, a single opening may be provided, or openings may be provided in two directions.

An example in which the supply portion 110 supplies the refrigerant to each of the plurality of openings of the opening portion 111 is illustrated, but the present exemplary embodiment is not limited to this configuration, and the supply portion 110 may be provided individually for each opening of the opening portion 111.

In the jet flow evaporative cooling system 400 according to the present exemplary embodiment, the heat generation unit 101 is disposed outside the space 120. Thus, it is not necessary to consider the effects of the characteristics of the refrigerant (the electrical insulation characteristic, the chemical characteristic, and the like) on the heat generation unit 101, and the refrigerant may be appropriately selected according to an intended performance of the jet flow evaporative cooling system 400. For example, in a case where the intended performance is to remove heat from a high heat flux, it is desirable to use a refrigerant containing water as a main component, since water has a very large vaporization heat that significantly affects the cooling ability and is also superior in terms of safety, cost, and the like. The space 120 inside the chamber 121 is in the reduced pressure environment in which the degree of vacuum is adjusted in advance using a means for exhausting air from the exhaust portion 123, or the like. The degree of vacuum may be adjusted so that the boiling point of the refrigerant is at the temperature intended by the user. For example, in a case where water is used as the refrigerant and the boiling point is to be set to approximately 33° C., the degree of vacuum in the space 120 can be set to 5 kPa. The jet flow evaporative cooling system 400 causes the refrigerant 113 to pass through the supply portion 110 and be jetted from the opening portion 111 to the cooling portion 104.

If the temperature of the cooling portion 104 becomes higher than the boiling point of the refrigerant due to the heat generated in the heat generation unit 101, the refrigerant vaporizes into steam, and the cooling portion 104 is cooled by the vaporization heat.

The steam of the refrigerant generated on the cooling portion 104 is exhausted from the exhaust portion 123, so that the degree of vacuum in the space 120 can be maintained. However, the present exemplary embodiment is not limited to this configuration.

The drain portion 122 is appropriately disposed so that some of the refrigerant 113 that has been jetted to the cooling portion 104 and remains unvaporized is drained to the outside of the chamber 121.

Here, the shape and the effect of the partition portion 112 are described with reference to FIGS. 8A to 8C. FIGS. 8A to 8C are enlarged views of the vicinity of the opening portion 111 in the jet unit 115. FIG. 8A illustrates an example of the shape of the partition portion 112, and FIGS. 8B and 8C illustrate examples of different patterns of the shape of the partition portion 112.

FIG. 8A illustrates a state in which water vapor generated by vaporizing the liquid at the cooling portion 104 comes into contact with an outer periphery portion of the jet unit 115 and condenses to form dew condensation (non-vaporized refrigerant) 116.

The partition portion 112 is provided to surround the openings of the opening portion 111 as in the present exemplary embodiment of the present disclosure, so that the non-vaporized refrigerant 116 can be prevented from entering the opening portion 111 and obstructing the jet flow of the refrigerant 113, and an instantaneous decrease in the cooling efficiency can be suppressed.

FIG. 8B illustrates a state in which an outer portion of the jet unit 115 and the partition portion 112 are integrated. As illustrated in FIG. 8B, a step is provided in a height direction with respect to each opening of the opening portion 111 and the opening portion of the partition portion 112 is set at a position lower than the opening portion 111, so that the non-vaporized refrigerant 116 can be prevented from entering the opening portion 111. In addition, it can be expected that a manufacturing cost and a space of the partition portion 112 are reduced by processing and integrating the shape of the partition portion 112 in the outer portion of the jet unit 115. It is desirable that an area of the partition portion 112 in FIG. 8B is sufficiently small so that the condensation of water vapor cannot remain therein.

FIG. 8C illustrates another pattern in which an inner periphery of the partition portion 112 is tapered. The shape of the partition portion 112 is not limited to those illustrated in FIGS. 8A to 8C, but may be any shape that has a step in the height direction with respect to each opening of the opening portion 111 and may be appropriately set by a user. The partition portion 112 does not have to be annular and only needs to surround the opening of the nozzle with a gap small enough to prevent the dew condensation 116 from entering the jet unit 115.

The jet flow evaporative cooling system 400 according to the present exemplary embodiment is configured as described above and thus can prevent condensed liquid from reaching the opening portion 111 of the jet unit 115. According to the present exemplary embodiment, it is possible to provide the jet flow evaporative cooling system 400 with stable cooling efficiency.

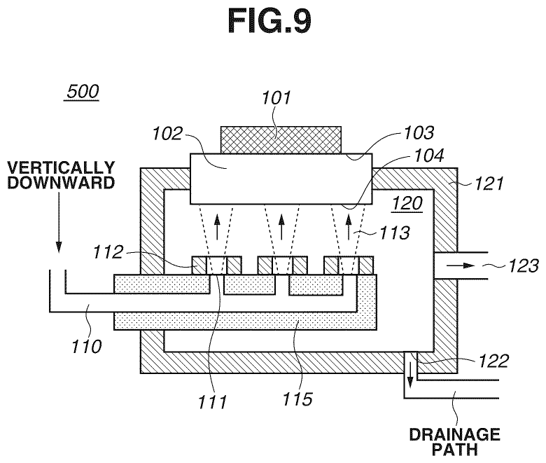

FIG. 9 illustrates a configuration of a jet flow evaporative cooling system 500 according to a fifth exemplary embodiment.

According to the fourth exemplary embodiment, the opening portion 111 is configured to jet the refrigerant 113 vertically downward toward the cooling portion 104 as described with reference to FIG. 7. On the other hand, as illustrated in FIG. 9, the jet flow evaporative cooling system 500 according to the present exemplary embodiment has a configuration in which the jet flow evaporative cooling system 400 according to the fourth exemplary embodiment is turned upside down, the chamber 121 is provided with respect to the heat generation unit 101, and the opening portion 111 jets the refrigerant 113 vertically upward toward the cooling portion 104. Other apparatus configurations and systems are similar to those according to the fourth exemplary embodiment, so that descriptions thereof are omitted.

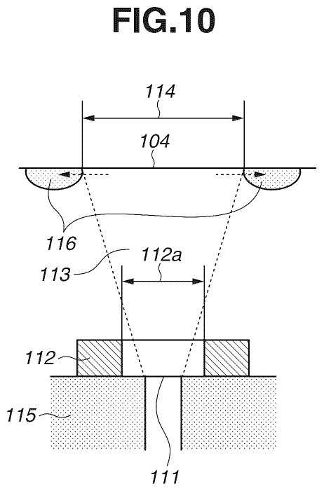

FIG. 10 illustrates a relationship between the jet flow collision range 114 and an opening range of the partition portion 112. In FIG. 10, the non-vaporized refrigerant 116, which is some of the liquid jetted to the cooling portion 104 and not vaporized, is pushed out of the jet flow collision range 114 where the liquid is jetted in the cooling portion 104 by the jet flow of the refrigerant 113 from the opening portion 111. Then, the non-vaporized refrigerant 116 accumulates and gradually falls by gravity on the jet unit 115. As illustrated in FIG. 10, an opening range 112a of the partition portion 112 is made narrower than the jet flow collision range 114, so that it is possible to prevent the non-vaporized refrigerant 116 from falling, directly entering the opening portion 111, and obstructing the jet flow of the refrigerant 113.

In other words, an opening range of the opening portion 111 is narrower than the opening range 112a of the partition portion 112. Here, the opening range 112a of the partition portion 112 means an opening range in an end potion of the partition portion 112, at which a step is provided in the height direction with respect to each opening of the opening portion 111. The jet flow evaporative cooling system 500 according to the present exemplary embodiment is configured as described above, and thus it is possible to provide the jet flow evaporative cooling system 500 with stable cooling efficiency. Specifically, it is possible to prevent some of the jetted liquid that has not been vaporized from falling due to gravity, reaching the opening portion 111, and obstructing the jet flow of the refrigerant 113.

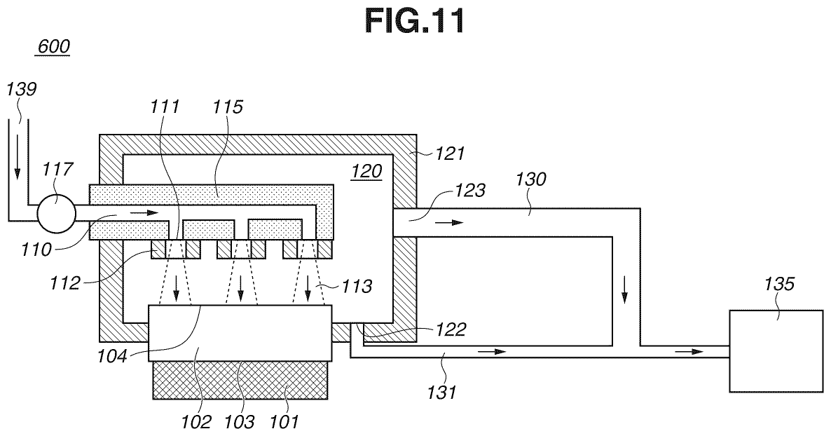

FIG. 11 illustrates an example of an overall configuration of a jet flow evaporative cooling system 600 according to a sixth exemplary embodiment of the present disclosure. FIG. 11 illustrates a configuration similar to the configuration of the jet flow evaporative cooling system 400 described according to the fourth exemplary embodiment, but the present exemplary embodiment is not limited to this configuration. The configuration of a jet flow evaporative cooling system 600 may be that described according to the fifth exemplary embodiment or may be appropriately combined with the configurations according to the first to fourth exemplary embodiments.

In the jet flow evaporative cooling system 600 illustrated in FIG. 11, the refrigerant before passing through the refrigerant supply valve 117 is maintained at a pressure equal to or higher than the atmospheric pressure. If the refrigerant supply valve 117 is opened, the refrigerant is supplied from the refrigerant delivery unit 139 to the supply portion 110 that supplies the liquid, due to a pressure difference with the pressure in the space 120 inside the chamber 121.

The steam of the refrigerant generated by vaporization on the cooling surface 104 is exhausted by the decompression pump 135 from the exhaust portion 123 disposed in the chamber 121 via the exhaust path 130.

The decompression pump 135 may be, for example, a gear pump, a water seal type pump, or a water ejector, but is not limited to these and may be appropriately selected according to a user's application and environment.

The refrigerant that has not been vaporized on the cooling surface 104 is also collected by the decompression pump 135 from the drain portion 122 via the drainage path 131, but the present exemplary embodiment is not limited to this configuration. The remained liquid may be drained by a separately provided pump (not illustrated) or the like.

Even if the heat generation amount of the heat generation unit 101 or the like is changed, the temperature of the cooling portion 104 can be stably controlled by controlling the flow rate of the refrigerant or the like, but, in order to simplify the description, a control system for controlling them and detailed components, such as a thermometer, a vacuum gauge, and a vacuum valve, are omitted here.

The entire configuration of the jet flow evaporative cooling system 600 is not limited to the above-described configuration and may be appropriately set according to a user's application, environment, and the like.

According to the present exemplary embodiment, the space 120 can be maintained at the reduced pressure state while cooling the cooling portion 104 by jet flow evaporative cooling, so that an increase in the boiling point of the refrigerant can be suppressed, and the temperature of the cooling portion 104 can be stably controlled.

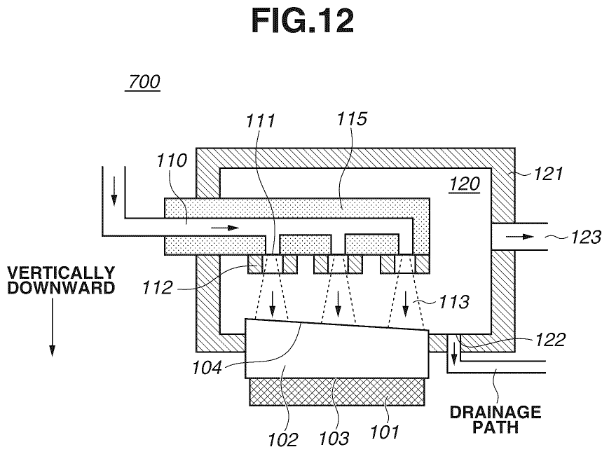

FIG. 12 is a schematic drawing illustrating a jet flow evaporative cooling system according to a seventh exemplary embodiment. The present exemplary embodiment is a combination of a part of the configurations according to the first to third exemplary embodiments and a part of the configurations according to the fourth to sixth exemplary embodiments. Specifically, the present exemplary embodiment is a combination of the incline of the cooling portion 104 according to the first to third exemplary embodiments and the partition portion 112 near the opening portion 111 according to at least one of the fourth to sixth exemplary embodiments. The combination according to the present exemplary embodiment is merely an example, and a jet flow evaporative cooling system may also be realized by appropriately combining the configurations of the other exemplary embodiments.

A jet flow evaporative cooling system 700 according to the present exemplary embodiment includes a configuration similar to that of the jet flow evaporative cooling system 100 illustrated in FIG. 1, except that the partition portion 112 is provided to surround the openings of the opening portion 111. According to the present exemplary embodiment, in addition to the effect of the first exemplary embodiment, even if the refrigerant condensed inside the chamber 121 moves near the opening portion 111, the partition portion 112 makes it difficult for the refrigerant to reach the opening portion 111. Accordingly, the jet flow of the refrigerant 113 from the opening portion 111 is less likely to be obstructed, and the temperature of the cooling portion 104 can be further stably controlled.

While the present disclosure has described exemplary embodiments, it is to be understood that some embodiments are not limited to the disclosed exemplary embodiments. The scope of the following claims is to be accorded the broadest interpretation so as to encompass all such modifications and equivalent structures and functions.

This application claims priority to Japanese Patent Application No. 2023-171697, which was filed on Oct. 2, 2023 and which is hereby incorporated by reference herein in its entirety.

What is claimed is:

1. A jet flow evaporative cooling system that cools a heat generation unit with a jet flow of liquid, the jet flow evaporative cooling system comprising:
a heat transfer portion integrally formed with a cooling portion configured to receive the jet flow of liquid and an arrangement portion on which the heat generation unit is arranged;
an opening portion configured to jet a liquid supplied from a supply portion to the cooling portion;
a drain portion configured to drain the liquid; and
a chamber configured to accommodate the opening portion, the drain portion, and the cooling portion and configured to not accommodate the arrangement portion therein,
wherein the chamber is maintained under a reduced pressure environment,
wherein the opening portion is configured to jet the liquid to the cooling portion,
wherein at least a part of the cooling portion is inclined, and
wherein the liquid is drained from the drain portion via the cooling portion.

2. The jet flow evaporative cooling system according to claim 1,
wherein, in the chamber, the cooling portion is arranged vertically below the opening portion, and at least a part of the drain portion is arranged vertically below the cooling portion.

3. The jet flow evaporative cooling system according to claim 1,
wherein, in the chamber, the cooling portion is arranged vertically above the opening portion, the drain portion is arranged vertically below the opening portion, and the opening portion is arranged vertically below the cooling portion and is arranged at a position different from a position of a vertical lower portion located at a lowest part of the cooling portion.

4. The jet flow evaporative cooling system according to claim 1, further comprising a jet unit configured to include the supply portion, the opening portion, and a partition portion,
wherein the partition portion is arranged near the opening portion to surround the opening portion in the jet unit.

5. The jet flow evaporative cooling system according to claim 4, wherein an opening range of the opening portion is wider than an opening range of the partition portion.

6. The jet flow evaporative cooling system according to claim 1,
wherein the cooling portion includes a groove portion formed by an upper groove portion and a lower groove portion, and
wherein at least a part of the upper groove portion and the lower groove portion is inclined in a direction in which the groove portion extends.

7. The jet flow evaporative cooling system according to claim 1, wherein the liquid mainly contains water.

8. The jet flow evaporative cooling system according to claim 1, further comprising:
a refrigerant delivery unit configured to deliver the liquid to the supply portion; and
a decompression unit configured to exhaust a gas generated by vaporizing the liquid in the chamber from the chamber via an exhaust portion.
